(19) United States
(12) Patent Application Publication
(10) Pub. No.: US 2024/0286398 A1
(43) Pub. Date: Aug. 29, 2024

(54) METHODS AND APPARATUS FOR PROCESSING AN ELECTROSTATIC CHUCK

(71) Applicant: ENTEGRIS, INC., Billerica, MA (US)

(72) Inventors: Chiranjeevi PYDI, Bethel, CT (US); Nathan RICHARD, Peabody, MA (US); Steven DONNELL, Burlington, MA (US); Sara MERCHEL, San Jose, CA (US); Caleb MINSKY, Medfield, MA (US); Cerel MUNOZ, North Chelmsford, MA (US); Yan LIU, Lexington, MA (US)

(21) Appl. No.: 18/645,650

(22) Filed: Apr. 25, 2024

Related U.S. Application Data
(63) Continuation of application No. 17/898,179, filed on Aug. 29, 2022.
(60) Provisional application No. 63/240,156, filed on Sep. 2, 2021.

(51) Int. Cl. B32B 41/00; B32B 7/12; B32B 9/00; B32B 9/04; B32B 15/20; B32B 37/08; B32B 37/12; H01L 21/683

(52) U.S. Cl. CPC B32B 41/00; B32B 7/12; B32B 9/005; B32B 9/041; B32B 15/20; B32B 37/08; B32B 37/12; B32B 2037/1253; B32B 2309/02; B32B 2309/04; B32B 2309/60; B32B 2309/72; B32B 2311/24; B32B 2315/02; B32B 2457/00; H01L 21/6831

(57) ABSTRACT

Described are techniques and equipment (apparatus) for processing an electrostatic chuck at controlled process conditions, including, as an example, for processing an electrostatic chuck during a step of curing an adhesive that forms a bond between two layers of the electrostatic chuck.

### CROSS-REFERENCE TO RELATED APPLICATIONS

This application is a continuation of U.S. patent application Ser. No. 17/898,179, filed Aug. 29, 2022. U.S. patent application Ser. No. 17/898,179 claims the benefit under 35 USC 119 of U.S. Provisional Patent Application No. 63/240,156, filed Sep. 2, 2021. The disclosures of U.S. Provisional Patent Application No. 63/240,156 and U.S. patent application Ser. No. 17/898,179 are hereby incorporated by reference in their entireties, for all purposes.

### FIELD

The following description relates to techniques and equipment (apparatus) for processing an electrostatic chuck, including, as an example, for processing an electrostatic chuck during a step of curing an adhesive that forms a bond between two layers of the electrostatic chuck.

### BACKGROUND

Electrostatic chucks (also referred to simply as “chucks,” for short) are used in semiconductor and microelectronic device processing. A chuck functions to hold in place a workpiece such as a semiconductor wafer or microelectronic device substrate to perform a process on a surface of the workpiece. The electrostatic chuck is adapted to support and secure the workpiece at an upper surface of the chuck by creating an electrostatic attractive force between the workpiece and the chuck. A voltage is applied to electrodes that are contained within the chuck to induce charges of opposite polarities in the workpiece and the chuck.

The chuck includes various structures, devices, and designs that allow the chuck to perform or that improve performance. Typical electrostatic chuck assemblies are multi-component, multi-layer structures that may include: an upper layer that has an upper surface to support a workpiece; a base layer that supports the upper layer; an adhesive that forms a bond between the upper layer and the base layer; electrical components such as electrodes, a conductive coating, and ground connections to control electrostatic charges of the chuck and a supported workpiece; and one or more cooling systems to control temperatures of the chuck and a supported workpiece. Various other components may include measurement probes, moveable pins used to support or to change a position of a workpiece relative to the chuck, and structure (e.g., “protrusions”) at the upper surface to support the workpiece at a small height above the flat upper surface.

A typical feature of an electrostatic chuck is a base that contains a cooling system. The cooling system includes an array of channels or passages formed within the interior of the chuck that allows a cooling fluid (e.g., gas, water, or another liquid) to flow through the interior of the chuck to remove heat from the chuck and to control a temperature of a supported workpiece during processing.

According to typical designs of electrostatic chucks, an adhesive layer is included as a layer of the chuck, such as to bond an upper layer to a lower base layer. The adhesive is typically of a type that is chemically curable. The adhesive is placed between the two layers of the chuck in an un-cured condition, and is then allowed or caused to cure over a period of time (a “cure time” or “cure period”) to form a secure adhesive bond between the layers.

### SUMMARY

The following disclosure relates to techniques and equipment (apparatus) for processing an electrostatic chuck, especially for processing an electrostatic chuck during a step of curing an adhesive that forms a bond between two layers of the electrostatic chuck.

The Applicant has determined that conditions for curing an adhesive layer of an electrostatic chuck can impact the quality of an electrostatic chuck. Cure conditions that are maintained at desired ranges can produce chucks of individually improved quality, and reduced rejection rates and re-working of chucks after a curing step. Cure conditions that fall outside of desired ranges can produce lower quality chucks individually, and can cause increased rejection rates and the need to re-work individual chucks. One process condition that can affect chuck quality is temperature of an adhesive during a step of curing the adhesive. Relative humidity in a curing atmosphere also affects the quality of the electrostatic chuck. A chuck that is cured in an atmosphere that contains too much humidity can result in condensation of moisture (liquid water) at the chuck surface during a curing step, especially if the temperature of the chuck is reduced during curing.

In one aspect, disclosed herein is an apparatus for processing an electrostatic chuck. The apparatus includes: a chamber that contains a chamber atmosphere at a chamber interior; a source of chamber purge gas adapted to supply chamber purge gas to the chamber; a source of temperature control fluid adapted to supply temperature control fluid to the chamber; and a temperature sensor to measure a temperature at the chamber interior.

In another aspect, disclosed herein is a method of processing an electrostatic chuck. The electrostatic chuck comprises: a first layer; a second layer; and an adhesive between the first layer and the second layer. The method includes: with the chuck located within an enclosed chamber, the chamber comprising: a chamber atmosphere, a temperature sensor; using an electronic controller to: control a temperature of the chuck, and control humidity in the chamber.

In yet another aspect, disclosed herein is an apparatus for processing an electrostatic chuck. The electrostatic chuck comprises: a first layer; a second layer; a fluid flow channel passing through at least one of the two layers; and an adhesive between the first layer to the second layer. The apparatus includes: a source of temperature control fluid connected to the fluid flow channel, and a source of purge gas connected to the fluid flow channel.

### BRIEF DESCRIPTION OF THE DRAWINGS

FIG. 1 shows an example of a chamber of an apparatus as described.

FIG. 2 shows an example of an apparatus as described, that includes multiple chambers.

FIG. 3 shows example components of an apparatus as described, and electronic connections between certain components.

### DETAILED DESCRIPTION

The following disclosure relates to techniques and equipment (apparatus) for processing an electrostatic chuck in an enclosed chamber and using controlled process conditions such as a controlled temperature of the chuck, and a controlled level of humidity. The techniques and equipment allow for the use of sensors, flow control, and electronic process control that are adapted to perform one or more of the following functions: setting or maintaining one or more process conditions, monitoring one or more process conditions, setting a time period for the process, and recording data of process conditions at the beginning of a process and during the process.

Electrostatic chucks that may be processed using the apparatus may be of any design and structure, with a particular example being electrostatic chuck designs that contain two layers that are bonded together by a chemically-curable adhesive that can be effectively cured by maintaining the adhesive at a constant temperature. The adhesive may be a chemically-curable adhesive such as a thermosetting polymer adhesive, one example being epoxy-based curable adhesives. When used to bond layers of an electrostatic chuck, the adhesive may be desirably cured at a cure temperature that is below ambient temperature, with the temperature of the chuck and the adhesive being held at a reduced (below ambient) temperature during a period of curing the adhesive. Other adhesives may be best cured by maintaining adhesive temperature at ambient temperature or above ambient temperature. The adhesive may be uncured (including partially cured) before the chuck is processed using the described apparatus, and can be processed using the apparatus to allow curing of the adhesive under controlled process (curing) conditions that are provided by the apparatus, which can be capable of setting, controlling, monitoring, or recording conditions of the apparatus and the electrostatic chuck during a process of curing the adhesive.

One layer of a chuck may be an upper layer of an electrostatic chuck, which includes a surface that is located adjacent to a bottom surface of a supported workpiece during use of the chuck. A second layer may be a lower layer, e.g., a base layer, which supports multiple layers above the base layer, including the upper layer. A curable adhesive is between the upper layer and the lower layer. One or more additional layers or devices (e.g., electrodes) may also be located between the upper layer and the base layer.

Each of the layers may be made of a material that is useful as an upper layer or a lower (base) layer of an electrostatic chuck. Example materials for either layer include metals (including metal alloys) and ceramic materials. Preferably, and as described herein as a primary example of a chuck that may be effectively processed using an apparatus as described: the base layer may include a cooling channel running through the interior of the layer; the base layer may be made of a metal such as aluminum or an aluminum alloy; the upper layer may be made of a ceramic; and the adhesive contacts both the base layer and the upper layer to form an adhesive bond between those two layers.

According to example methods of the present description, an electrostatic chuck can be processed at process conditions that are set, controlled, or both, and that are optionally and preferably monitored and recorded during processing of an electrostatic chuck. The process conditions may include any one or more of: a temperature of the chuck, humidity in the chamber, and an amount of time allowed for a performing a process or individual, separate portions of a process.

A process for preparing an electrostatic chuck is performed within a chamber of an apparatus as described, for a desired amount of time that is sufficient to allow the process to be started and completed, and at desired process conditions such as temperature of the chuck and humidity of the curing atmosphere. A process condition can be produced at a beginning or early portion of the process and then maintained (controlled) during all or a portion of the process, and may be optionally and preferably monitored and recorded during the process, until the process is complete. The amount of time for which the process is performed, i.e., the duration of the process, and amounts of time of particular steps of an overall process, may be desired, predetermined periods of time for a process of curing an adhesive.

During processing an electrostatic chuck, for example for curing an adhesive that is part of the chuck, the electrostatic chuck may be held at a desired, constant processing temperature (“curing temperature”), held below a maximum or above a minimum temperature, or within a range of temperatures. The processing temperature may be any temperature, which may be ambient, above ambient (elevated), or below ambient (cooled).

For particular examples of electrostatic chucks, and for a process of curing an adhesive of the chuck, a useful process temperature (curing temperature) can be a temperature that allows for complete and effective curing of the adhesive during a curing period. For adhesives of different chemistries, a cure temperature may vary, with broadly useful cure temperatures being in a range from negative 25 degrees Celsius (−25 C) to 100 degrees Celsius. For certain epoxy adhesives that are currently useful or preferred for bonding electrostatic chucks, a cure temperature may be below an ambient (room) temperature, e.g., below 25 or 20 degrees Celsius, for example a temperature in a range from 5 to 25 degrees Celsius, or from 10 to 20 degrees Celsius.

For certain examples of electrostatic chucks that are used at operating conditions that include a chuck temperature that is below ambient temperature, the adhesive of the chuck is designed to be stable at a below-ambient temperature operating condition. According to methods as described, an adhesive of a chuck may be cured at a temperature that is the same as a temperature that the chuck will be maintained during use of the chuck, which may be a below-ambient temperature. As a separate advantage, a cure temperature that is below ambient temperature can also produce a desired shape of a surface of an electrostatic chuck.

A particular temperature for a process of curing an adhesive of an electrostatic chuck may be selected based on the type of adhesive being cured, the temperature at which the chuck and adhesive are designed to operate, and other features of the curing step such as the amount of time over which the cure temperature is maintained during a curing step.

To control a temperature of a chuck and maintain a desired temperature of the chuck during processing, a temperature control fluid is provided to the chamber interior and is used to maintain the temperature of the chuck also held in the chamber, by the temperature control fluid being placed in thermal contact with the electrostatic chuck. In preferred embodiments, the temperature control fluid can be a liquid, such as water, that is flowed into the chamber and is placed in direct contact with the chuck by any useful method. In specific example embodiments, the temperature control fluid can be used to control the chuck temperature by being flowed through a channel that runs through an interior of a layer of the chuck (e.g., through a base layer of a chuck). The temperature control fluid can be flowed in thermal contact with the chuck at a flow rate and temperature that hold the chuck at a temperature that is desired for processing, e.g., for a step of curing an adhesive, which will be a temperature that is approximately the same as the temperature of the cooling fluid.

A temperature control fluid (e.g., cooling fluid) may be provided to an inside (interior) of a chamber from a source of temperature control fluid, such as a “chiller” or a “heater.” The temperature control fluid may flow through a conduit that leads from a temperature control fluid source and into the chamber, where the temperature control fluid can be placed in thermal contact with the chuck. In example methods, the conduit connects to an opening (“inlet”) in the electrostatic chuck that connects to a channel (sometimes referred to as a “fluid flow channel” or a “cooling channel”) that runs through a layer of the electrostatic chuck. The channel includes a second opening (“outlet”). A second conduit has one end that connects to the second opening of the channel (to the channel “outlet”), and a second end that is located at an exterior of the chamber. During operation, temperature control fluid flows through the first conduit, through the inlet and through the entire path of the channel within the chuck, exits the channel through the outlet and is received by the second conduit. The second conduit carries the temperature control fluid out of the chamber, for example back to the source of temperature control fluid.

The apparatus includes one or more temperature sensors (e.g., thermocouples or other temperature sensing devices) at the interior of the chamber that can be used to measure and optionally monitor a temperature within the chamber during a process. The temperature that is measured and optionally monitored may relate to the electrostatic chuck, and can be measured directly or indirectly during processing of the chuck to determine whether the chuck is at a desired processing temperature, such as within a range of temperatures above and below a desired cure temperature, which may be equal to or approximately equal to a temperature of the temperature control fluid (e.g., cooling fluid).

A location of a temperature measurement and a manner of measuring temperature may be as desired and useful for a particular process, electrostatic chuck, apparatus, chamber, etc. A temperature sensor may measure a surface temperature of a chuck, e.g., for example by being located at or by reading a temperature at a surface of the chuck. Alternately, a temperature sensor may measure a temperature of a temperature control fluid that is in thermal contact with the chuck, for example as a temperature control fluid passes into, through, or from a fluid flow channel of an electrostatic chuck. Multiple temperature sensors may be useful.

According to a currently-preferred example apparatus and method, an apparatus may include two temperature sensors located within a chamber. One temperature sensor can be located and configured to measure a temperature of a temperature control fluid (e.g., cooling water) as the fluid flows through an inlet (including nearby conduits) of a cooling channel of an electrostatic chuck. A second temperature sensor can be located and configured to measure a temperature of the temperature control fluid (e.g., cooling water) as the fluid flows from the cooling channel, e.g., through an outlet (including nearby conduits) of the cooling channel of the electrostatic chuck.

Optionally, a chamber may also include one or more pressure sensors to monitor pressure of temperature control fluid (e.g., a liquid cooling fluid) that flows within the chamber. According to a currently-preferred example apparatus and method, an apparatus may include two pressure sensors located within a chamber to monitor pressure of temperature control fluid at two locations. One pressure sensor can be located and configured to measure a pressure of temperature control fluid (e.g., cooling water) as the fluid flows through an inlet (including nearby conduits) of a cooling channel of an electrostatic chuck. A second pressure sensor can be located and configured to measure a pressure of temperature control fluid (e.g., cooling water) as the fluid flows through an outlet (including nearby conduits) of the cooling channel of the electrostatic chuck.

During use of the apparatus for processing an electrostatic chuck, another process condition that can be controlled and optionally monitored and recorded during use of the apparatus is relative humidity of a chamber atmosphere contained in an enclosed chamber. A step of “controlling” humidity, and the term humidity “control,” refer broadly to any method that maintains a relative humidity of a chamber atmosphere to be sufficiently low to prevent moisture contained in the gaseous atmosphere from forming on a surface of a chilled electrostatic chuck within the atmosphere. A method of “controlling” humidity does not require that a specific humidity level (i.e., percent relative humidity at a specific temperature), or a maximum humidity level be measured and maintained within an enclosed chamber during a process step. “Controlling” humidity specifically does not require (but may optionally include, if desired) a feedback-type control system or a step of quantitatively measuring and adjusting an amount of gaseous moisture of a chamber atmosphere, such as by measuring and maintaining humidity of a chamber atmosphere to be within a specified or pre-determined range of relative humidity, or at a desired relative humidity “set-point,” or below a maximum relative humidity value, or the like.

Control of humidity to prevent condensation of moisture at a chuck surface can be accomplished by non-feedback-style, e.g., qualitative control of an amount of moisture contained in a chamber atmosphere. In particular example methods, controlling humidity of a chamber atmosphere can be accomplished by adding dry gas (purge gas) to the chamber during a process.

Humidity control may include maintaining a consistent (e.g., continuous or semi-continuous) flow of a dry purge gas to the chamber during a process step. The amount (volume, volumetric flow rate) of purge gas that is delivered to a chamber can be determined empirically (e.g., by trial-and-error), or based on calculation. The purge gas can be delivered to the chamber with the amount of the purge gas being controlled and optionally monitored by use of a flow meter connected to a process controller (described herein).

In a particular example method, at a start of a process, an enclosed chamber originally contains an electrostatic chuck contained (e.g., supported) within a chamber atmosphere that is composed entirely of ambient air, for example ambient air that is contained in a clean room in which the chamber is housed. The air that is initially contained in the enclosed chamber will have a relative humidity and a temperature of a typical clean room, which may be in a range from below 10 percent to approximately 50 percent relative humidity, such as from 30 to 40 percent relative humidity, at an ambient temperature (e.g., from 20 to 23 degrees Celsius). Having a relative humidity within this range, the ambient air that makes up the chamber atmosphere contains a sufficient concentration of moisture (gaseous water) that if an electrostatic chuck were to be cooled to a sufficiently reduced temperature, below atmospheric temperature, in the air atmosphere contained by the chamber, such as during a process of curing an adhesive of the chuck at below ambient temperature, moisture that is contained in the air will condense as liquid water at a surface of the chuck.

To prevent condensation of moisture as liquid water on a surface of the chuck upon cooling the electrostatic chuck within the chamber, the concentration of moisture in the chamber atmosphere during the processing step can be controlled. At a start of a process step, a chamber atmosphere may be presented to the chamber, or adjusted within the chamber, to exhibit a relative humidity that will not result in condensation of liquid water onto the chuck surface during processing that includes reducing the temperature of the chuck.

When the chamber atmosphere in the chamber is made of ambient air, e.g., air contained in a clean room, the concentration of moisture in the ambient air atmosphere can be reduced to prevent condensation on a surface of a chuck that is cooled to a below-ambient temperature. For example, during processing an electrostatic chuck, the relative humidity of a chamber atmosphere that is contained in an enclosed chamber may be reduced and controlled to a level that will not cause condensation on a chuck surface, by adding an amount of additional gas to the air to reduce the concentration of water vapor in the air that makes up the chamber atmosphere. The added gas is referred to as a “chamber purge gas,” and contains a reduced amount of water relative to the ambient air, preferably no water, e.g., less than 5, 2, or 1 percent by volume water vapor, and is considered to be a “dry” gas. A chamber purge gas may be any type of gas that when added to the chamber atmosphere (e.g., of ambient air) will reduce the concentration of moisture (water vapor) in the chamber atmosphere. Examples include dry (moisture-less) gases such as dry nitrogen and clean dry air (CDA).

The chamber purge gas can be added to a chamber during and throughout a process in a continuous or semi-continuous manner. The amount of chamber purge gas that is added to the chamber, e.g., a volumetric flow or flow rate, can be an amount that will maintain the relative humidity level of the chamber atmosphere to a level that will not result in condensation of liquid water at a surface of an electrostatic chuck that is being processed within the chamber at a processing temperature (e.g., curing temperature) of the electrostatic chuck.

The chamber purge gas can be added to a chamber after an electrostatic chuck is placed within the chamber and the chamber is closed, during processing of the chuck. The amount and type of chamber purge gas added to the chamber atmosphere will increase the concentration of the chamber purge gas within the chamber, and reduce the concentration of water vapor in the chamber atmosphere. With a useful flow of chamber purge gas into the chamber during a process, an electrostatic chuck within the chamber can be processed by steps that include reducing the temperature of the chuck, without causing moisture (water vapor) that is contained in the chamber atmosphere to become condensed as liquid water on the cooled chuck surface. The process does not require that the relative humidity of the chamber atmosphere be measured, used in a feedback control loop, or specifically set or maintained at a particular (quantitative) level or maintained below a set maximum value, during the process. Humidity control can be accomplished by adding an amount of purge gas to the chamber (e.g., as a measured and controlled flow rate) during the process, with the amount being is sufficient to produce and maintain a chamber atmosphere that does not result in condensation of moisture at a cooled chuck surface.

A useful amount of chamber purge gas can be added to the chamber by a method that controls or measures a flow of chamber purge gas into the chamber during a process. The amount of the chamber purge gas can be any amount that will prevent condensation on a surface of the chuck during a particular process performed on the chuck within the chamber.

By one method of adding chamber purge gas to the chamber, the chamber purge gas may be added to the chamber in a continuous or semi-continuous manner, during a process, through a flow meter that measures the amount (by volume, mass, or otherwise) of the fluid that passes into the chamber. The amount of the gas that is added to chamber interior is an amount that is calculated or empirically determined to reduce the relative humidity of the chamber atmosphere to a desired relative humidity level, which will not result in condensation during processing.

Optionally, but not as a requirement of a described method or apparatus, a pressure sensor can be included at the chamber interior to measure the pressure of the gaseous chamber atmosphere, as the purge gas is added to the chamber. The amount of the chamber purge gas that is added to the chamber can be an amount to produce a desired positive pressure within the closed chamber, such as a pressure in a range from 1.2 to 4.0 atmospheres (absolute), e.g., from 1.5 to 3.5 atmospheres (absolute).

Another process condition that can be set and monitored is the amount of time that the process or a process step is performed. For a process of curing an adhesive, various individual steps are performed for different periods of time during the overall process. Example steps include: a step of controlling temperature of the chuck by contacting the chuck with temperature control fluid; a step of flowing purge gas to the chamber interior; a step of passing a channel purge gas through a channel of a chuck, among others. In example methods, an amount of time that a chuck is held in a chamber under a controlled or monitored process condition can be measured and controlled using a timer. A process performed on an electrostatic chuck within the chamber and controlled chamber environment can be performed by steps that each are in effect for a pre-determined period of time.

During an example process of curing an adhesive of an electrostatic chuck, an electronic controller may control one or more of: an amount of time that a temperature of a chuck is contacted with temperature control fluid; a flow rate of the temperature control fluid; a temperature of the temperature control fluid; an amount of time of flowing chamber purge gas to the chamber interior; a flow rate of the chamber purge gas; an amount of time for passing a channel purge gas through a channel of a chuck; a flow rate of channel purge gas; among others.

For example processes that involve curing a chemically-curable adhesive in a chamber of an apparatus as described under uniform conditions, example cure periods and an amount of time that a cooling fluid passes through a cooling channel of a chuck can be at least 30 minutes, 60 minutes, or 90 minutes, such as at least 3, 5 or 10 hours, or up to or exceeding 12, 16, or 24 hours. During a cure period, the chuck remains within the enclosed chamber, the chamber atmosphere is controlled to prevent condensation on a surface of the cooled chuck (e.g., by a flow of chamber purge gas into the chamber), and the chuck temperature is controlled using temperature control fluid, and optionally monitored, to ensure that the chuck temperatures remains within a desired cure temperature range, e.g., below a maximum temperature.

After the process is performed for a desired amount of time under controlled conditions, the flow of temperature control fluid through the chamber and through the channel of the chuck can be stopped. With the chuck still held inside the chamber, a temperature control fluid that is in the form of a liquid, such as liquid water, can be removed from the channel, i.e., “purged” from the channel and the channel can be dried. Removing the temperature control fluid from the channel, and drying the channel, can be performed in any manner, and by any of one or more steps. By an example method, a temperature control fluid can be removed from the channel, and the channel can be dried, by passing a channel purge gas through the channel. The amount of time of passing the channel purge gas through the channel, and the flow rate of the channel purge gas, can be controlled by the electronic processor.

The channel purge gas can be passed through the same flow conduit that is used to pass the temperature control fluid through the channel of the electrostatic chuck. For example, a channel purge gas may flow through a conduit that leads from a channel purge gas source and into the chamber, where the conduit connects to an opening (“inlet”) in the electrostatic chuck that connects to a channel (sometimes referred to as a “fluid flow channel” or a “cooling channel”) that runs through a layer of the electrostatic chuck. The channel includes a second opening (“outlet”). A second conduit connects to the second opening at one end of the conduit, and to an exterior of the chamber at a second end of the conduit. The channel purge gas can be caused to flow through the first conduit, through the inlet and through the entire path of the channel within the chuck, and eventually to exit the channel through the outlet and is received by the second conduit. The second conduit carries the channel purge gas the chamber, for example back to the source of the channel purge gas. The inlet and the outlet may be located at either surface of the electrostatic chuck (top or bottom, upper or lower), and the inlet and outlet may both be on the same surface or on different surfaces.

A channel purge gas can be any gas that is capable of removing liquid from a channel of a channel of a chuck, or drying a channel of a chuck, and preferably removing trace moisture from the surface of the channel to leave a dry channel. The channel chamber purge gas may preferably contain a low amount of water (moisture), preferably no water, e.g., less than 5, 2, or 1 percent moisture by volume water vapor, and is considered to be a “dry” gas. Examples of channel purge gases include dry (moisture-less) gases such as dry nitrogen and clean dry air (CDA). A source of channel purge gas may be the same as a source of chamber purge gas for a chamber or for an apparatus as described.

During a process performed on an electrostatic chuck, within the chamber, under controlled conditions, the process conditions present during a process can be monitored and recorded. A purpose of monitoring conditions that occur during a process is to ensure that process conditions are within a desired range and to allow for adjusting or stopping a process if a condition falls out of a set range. For example, if a chuck temperature is monitored during a curing process, and the temperature is outside of a desired range (e.g., exceeds a maximum temperature or a minimum temperature), an apparatus (e.g., by an electronic controller) can sound a warning or an alarm to notify an operator of the apparatus that the temperature is out of range. A temperature that is out of range may indicate a malfunction of the apparatus, such as a leak of temperature control fluid, or a malfunctioning source of temperature control fluid (e.g., a “chiller”).

Alternately, or in addition, a relative humidity sensor, which is optional and not required, can monitor relative humidity of a chamber atmosphere during use of the chamber. If relative humidity within the chamber falls outside of a desired range, an apparatus (e.g., by an electronic process control) can sound a warning or an alarm to notify an operator of the apparatus that the relative humidity is out of range. A relative humidity that is out of range may indicate a malfunction of the apparatus such as a malfunctioning or depleted source of chamber purge gas.

Likewise, other sensors such as pressure sensors within the chamber may be monitored, and if a pressure falls outside of a desired (pre-set) range, the apparatus can produce a signal, e.g., a warning or an alarm, to notify an operator of the apparatus that the pressure or other condition is out of range.

The process conditions that are monitored during a process performed on a particular electronic chuck may preferably be recorded. In the event that a chuck is subsequently tested or used and found to be defective, the conditions (e.g., chuck temperature, relative humidity) that were in place in the chamber when a particular chuck was processed can be reviewed to determine if a condition was proper or out of range during processing of the particular chuck.

According to a particular example, a method can be performed in an apparatus as described, to cure an adhesive of an electrostatic chuck under controlled and monitored process conditions. The method can include placing an electrostatic chuck within a chamber as described. The electrostatic chuck can be of a design that includes a chemically-curable adhesive that bonds together two layers of the chuck. The chuck may include a first layer, a second layer, and an adhesive that bonds the first layer to the second layer. The adhesive may be uncured, meaning completely uncured or partially cured (pre-cured). An adhesive that is partially cured may have been allowed to cure for a short period of time that allows the adhesive to partially solidify. An example time period for pre-curing may be in a range from 30 minutes to 3 hours, depending on the adhesive.

A process of curing the adhesive is performed within a chamber of an apparatus as described, while setting, controlling, or maintaining one or more process conditions within the chamber while the adhesive cures. The process conditions can include maintaining the chuck at a temperature that is below ambient temperature (e.g., below 20 degrees Celsius). The method can also include providing a chamber atmosphere that has a relative humidity that is sufficiently low to not cause condensation of moisture (water) from the chamber atmosphere onto a reduced-temperature surface of the chilled electrostatic chuck.

Example methods can include placing the chuck into the chamber and closing an access port of the chamber. The chamber will be closed, with the chamber interior being enclosed, but the chamber is not necessarily sealed in an air-tight manner and is not required to be sealed in an air-tight manner for use according to the present description. In some example methods of cuing an adhesive of an electrostatic chuck, a flat weighted surface such as a ceramic plate is placed on the top surface of the electrostatic chuck during the adhesive curing step to maintain the position of the upper layer during the cure step.

In example methods, when the chamber is first closed at a start of a process, the chamber will contain an initial atmosphere of ambient air from the environment of the apparatus, which may be a clean room. After closing the chamber, an amount of chamber purge gas can be added to the chamber to reduce the humidity of the chamber atmosphere, to prevent condensation of water on the chuck surface when the surface is cooled. Chamber purge gas can be added to the chamber in a continuous or semi-continuous manner to during the process, to maintain a relatively dry chamber atmosphere that does not result in condensation of moisture on a surface of the chilled electrostatic chuck at any time during the process.

The curing process can be performed by maintaining the temperature of the chuck, within the chamber, at a suitable curing temperature for a desired amount of time. The temperature may be controlled to be constant, i.e., uniform, throughout the process, or at least may be controlled to not exceed a pre-determined maximum chuck temperature. By a preferred method, a cooling fluid (chilled water) is flowed through a cooling channel that passes through a layer of the chuck to control the temperature of the chuck during the process.

Using an electronic controller during the curing process, the apparatus can perform one or more of: measure a temperature of the chuck (e.g., directly at a surface of the chuck, by measuring cooling water that flows through a channel of the chuck, or otherwise); measuring humidity in the chamber by using a relative humidity sensor; measure pressure of the chamber atmosphere within the chamber, using a pressure sensor; control the amount of time that the curing step is performed, using a timer. If, during the curing process, a condition such as a temperature, pressure, or relative humidity of the atmosphere falls outside of a pre-determined operating range, the electronic controller can emit a signal, such as a warning, that an operator of the apparatus will detect.

After completing the curing process, with the chuck still within the chamber, a channel purge gas can be flowed through the channel of the chuck. The channel purge gas removes liquid from the channel, dries the channel, or both. After liquid is removed from the channel and the channel is dried, the chuck is removed from the chamber.

For performing a process as described, a useful apparatus includes one or more chambers, various sensors located at each of the chambers (to measure relative humidity, temperature, pressure of a liquid or gas), supplies and flows fluids to the chamber (chamber purge gas, channel purge gas, temperature control fluid), and an electronic controller to receive electronic signals from the sensors or system components. The chamber, sensors, fluid sources, fluid flow controls such as valves and flow meters, and electronic controller operate together to process one or more electrostatic chucks under controlled and preferably monitored and recorded process conditions.

A useful controller can be any electronic device, e.g., an electronic control or computing device, that is capable of electronically receiving and transmitting control signals between devices or components of an apparatus as described. The controller may be a computerized control system that contains a central processing unit and programmable control software such as a programmable or process logic controller (“PLC”), a laptop computer, a desktop computer, a tablet computer, a smart phone, or the like. A controller of an apparatus that includes multiple chambers, each with a chamber atmosphere, one or multiple sources of temperature control fluid, and one or multiple sources of purge fluids (chamber purge fluid or channel purge fluid), can be programmed to run a different process in each chamber. A temperature control fluid delivered to one chamber of an apparatus may have a different temperature than a temperature control fluid delivered to a different chamber of the apparatus; the temperatures control fluids may be received from two different temperature control fluid sources, each delivering fluid of a different temperature to the two chambers.

The controller can also control flow of cooling fluid through a bypass loop in a chamber that flows cooling fluid through the chamber but not through the electrostatic chuck. The controller may flow the cooling fluid through the bypass loop, for example, when the chamber does not contain an electrostatic chuck being processed, or when flow of cooling fluid is through an electrostatic chuck in the chamber is stopped, such as during channel purge using purge gas. A flow conduit of the bypass loop contains cooling fluid flowing at a rate of flow that may be the same as a rate flowing through the cooling channel of an electrostatic chuck during a process step, such as an adhesive cure step. The cooling fluid flows through the conduit of the bypass loop and back to the source of cooling fluid, and can be recycled through the system. The bypass loop functions to maintain controlled flow rate of the cooling fluid in chambers that all receive cooling fluid from one source. The bypass loop also allows for introduction and removal of electrostatic chucks from the chamber without shutting off the cooling fluid, providing a consistent flow of water through the system at times when chillers are on.

In more detail, a useful or preferred apparatus includes one or more chambers, each chamber containing a chamber interior that is able to contain an electrostatic chuck during processing. A chamber is defined by sidewalls, which are optionally insulated, at least one sidewall comprising a panel or door that can be opened and closed to allow access to the interior space of the chamber (a.k.a. “chamber interior”), and while open will allow an electrostatic chuck to be passed into the interior space and held by a support, or to be removed from the interior space. After placing a substrate within the chamber interior, the panel or door can be closed to enclose the chamber interior.

A useful chamber interior may be enclosed and need not be “sealed.” A chamber interior that is “enclosed” refers to an interior that defines a space that is closed on all sides. The enclosed chamber may be non-sealed, meaning that the chamber is not air-tight but allows for some movement of air between the chamber interior and a chamber exterior, such as through small openings or minute paths located in the chamber structure. The air pressure within the chamber will be approximately equal to the air pressure in a surrounding environment of the apparatus, e.g., a clean room, or possibly greater due to a flow of purge gas into the chamber. The chamber is not required to be sealed in an air-tight manner that substantially prevents gas from entering or exiting the interior space during use. An enclosed chamber that is useful according to the present description can specifically be enclosed but not air-tight or sealed.

Each chamber defines an interior space that can be closed to contains an enclosed atmosphere (“chamber atmosphere”). Features such as relative humidity and pressure of each of the one or more chamber atmospheres may, as desired, be controlled, monitored, or recorded during operation of the apparatus to process an electrostatic chuck. A temperature of the electrostatic chuck (e.g., as measured by temperature control fluid (e.g., cooling water) that is in thermal contact with the electrostatic chuck) can be controlled, monitored, or recorded during operation of the apparatus for processing the electrostatic chuck. One single chuck can be contained in each of the one or more chambers, and any one or more process conditions within each of the one or more chambers can preferably be controlled separately from any process condition of a different one of the one or more chambers.

In an example apparatus and process, an electronic controller receives separate electronic inputs from the sensors of each of the one or more chambers. The controller may monitor and record each of the separate electronic inputs while an electrostatic chuck is being processed within the chamber. The controller can independently supply different fluids from the different sources to each chamber, with the different fluids being delivered at any of: different flow rates, different amounts, different temperatures, etc.

The apparatus can include a source of cooling fluid that can be used to contact an electrostatic chuck during processing, to maintain a desired temperature of the chuck. Optionally, the apparatus may include two different sources of cooling fluid for delivering a different flow of cooling fluid to two different chambers of an apparatus. The different sources of cooling fluid may be held at different temperatures.

The apparatus can include a source of gas, referred to as chamber purge gas, that is useful to supply chamber purge gas to a chamber interior.

The apparatus can include a source of gas, referred to as cooling channel purge gas, that is useful to supply channel purge gas to a channel of an electrostatic chuck, to purge or dry the channel. The source of the channel purge gas may be the same or different from the source of the chamber purge gas.

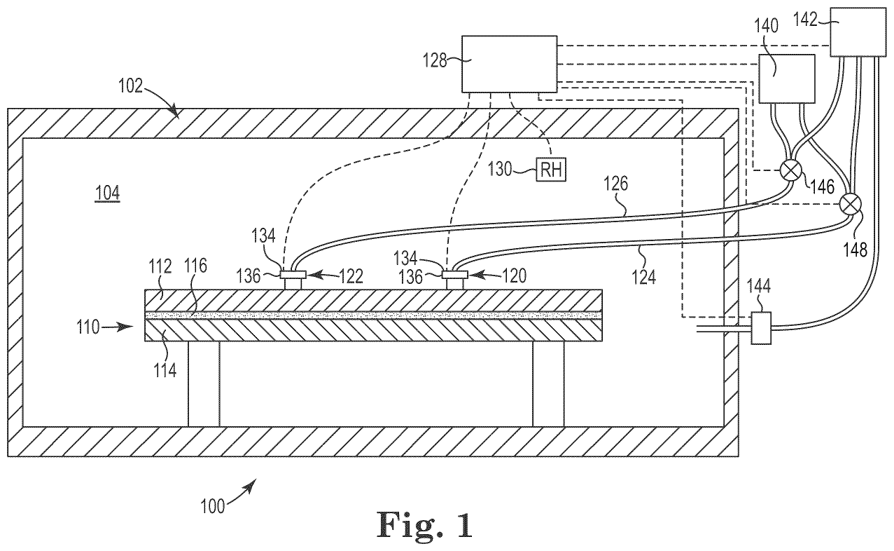

Referring to FIG. 1, illustrated is an example of an apparatus as described. Apparatus 100 includes chamber 102, with chamber interior space 104. Chamber interior space 104 is closed (“enclosed”) but not sealed in an air-tight manner during use. Interior space 104 houses electrostatic chuck 110 in the enclosed chamber atmosphere.

Electrostatic chuck 110 includes upper layer 112, base layer 114, and adhesive layer 116. At least one of base layer 114 or upper layer 112 includes a fluid flow channel (not specifically shown), e.g., a cooling channel, that extends as an array within the layer and through which a fluid (e.g., a liquid such as a cooling liquid) can be flowed to control a temperature of chuck 110. Inlet 120 connects to one end of the channel and outlet 122 connects to a second end of the channel.

Conduit 124 is connected to inlet 120 and allows a fluid such as a temperature control fluid or a channel purge gas to be flowed from an exterior location, to inlet 120. The exterior location of conduit 124 can be connected to source 140 of temperature control fluid (e.g., a chiller that supplies chilled water), to source 142 of channel purge gas, or to both. Flow meter 144 can be used to control, meter, and measure an amount of purge gas that is added to space 104.

Conduit 126 is connected to outlet 122 and allows a fluid such as a temperature control fluid or a channel purge gas to be flowed from an outlet 122 to an exterior location. The exterior location of conduit 126 can be connected to source 140 of temperature control fluid (e.g., a chiller that supplies chilled water), to source 142 of channel purge gas, or to both using a switch or valve (146, 148).

Sensors that may be present in chamber 102 (but are not required) can include: a temperature sensor, a gas pressure sensor, a relative humidity sensor, a liquid pressure sensor, or combinations of these. Apparatus 100 also includes electronic controller 128, which is connected to the sensors, to fluid sources, e.g., 140, 142, to flow meter 144, and to switches or valves 146 and 148. Electronic connections between controller 128 and devices or components of apparatus 100 are indicated by dashed lines. Connections may be direct, wired, wireless (e.g., Bluetooth), through a local area network, a virtual private network (VPN), an ethernet connection, an internet connection, or the like.

In the illustrated example apparatus 100, one or more relative humidity sensors 130 (optional and not required) are present within chamber interior space 104, with each sensor 130 being capable of sending an electronic signal to controller 128 to indicate a relative humidity of the chamber atmosphere within space 104. One or more gas pressure sensors (not shown) may also be present within space 104, with each sensor being capable of sending an electronic signal to controller 128 to indicate a pressure of the gaseous chamber atmosphere within space 104.

Also in example apparatus 100, temperature sensors and liquid pressure sensors measure and monitor temperature and pressure of a temperature control fluid that passes through conduits 124, 126, and a cooling channel of chuck 110. In specific, temperature sensor 134 measures a temperature of a temperature control fluid as the fluid passes from conduit 124, at input 120, into the cooling channel (not shown). A second temperature sensor 134 measures a temperature of the temperature control fluid as the fluid passes from the cooling channel through output 122 to conduit 126. The temperature measurements are transmitted to processor 128. Liquid pressure sensor 136 measures a pressure of the temperature control fluid as the fluid passes from conduit 124, at input 120, into the cooling channel (not shown) or alternatively a liquid pressure sensor can measure pressure of the temperature control fluid as the fluid enters chamber 102. A second liquid pressure sensor 136 measures pressure of the temperature control fluid as the fluid passes from the cooling channel through output 122 to conduit 126. The liquid pressure measurements are transmitted to processor 128.

Also illustrated as part of apparatus 100 is purge gas source 142, which, in cooperation with controller 128 and flow meter 144, is adapted to supply chamber purge gas to space 104 of chamber 102 in a continuous or non-continuous manner during a process.

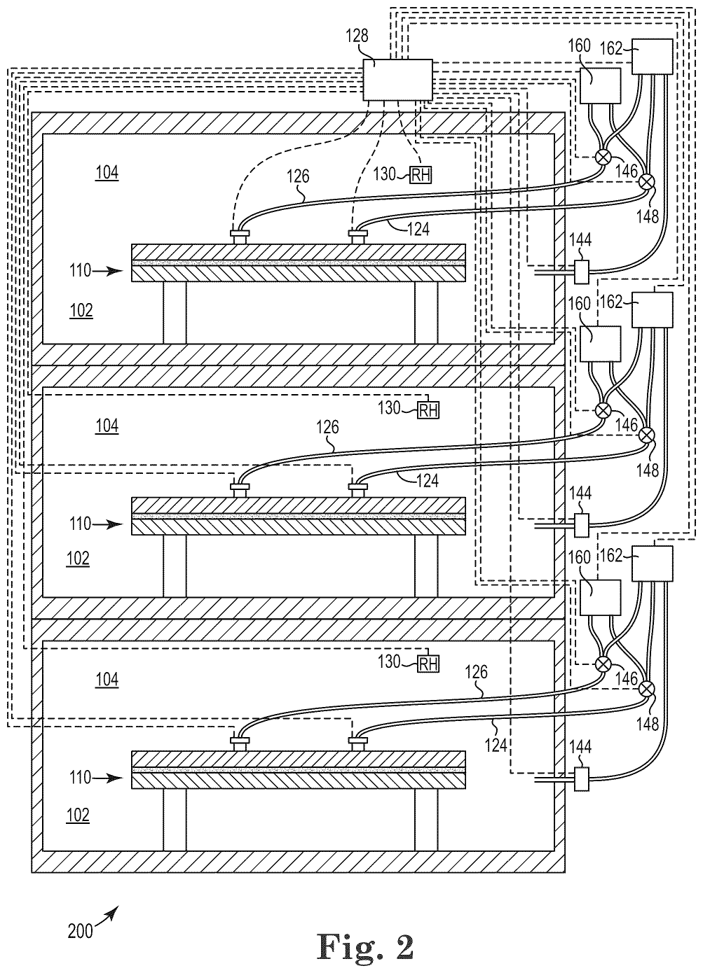

Referring to FIG. 2, illustrated is apparatus 200, which includes three separate chambers 102 in a vertically-stacked configuration. The stacked chambers 102 can be supported as part of a single apparatus connected and supported, for example, by a single frame, rack, chassis, or carrier (not shown). In useful or preferred example apparatuses, the chambers can be stacked and supported vertically.

FIG. 2 shows apparatus 200 that includes three different chambers, 102, each adapted to contain a single electrostatic chuck 100 for processing in a controlled atmosphere within enclosed chamber interior space 104. The apparatus includes one source 162 of purge gas (more sources may be used if desired), and one or more sources 160 of temperature control fluid. At FIG. 2, each chamber 102 of apparatus 200 and its constituent components (space 104, chuck 110, sensors, etc.) have similar structures and numerical designations as in FIG. 1, other than sources 140 and 142.

Each of the three illustrated chambers 102 is connected to a source of temperature control fluid. The source 160 for each chamber may be the same source, or a different source. In example apparatuses and methods, source 160 supplies cooling water at cooling water temperature to each of the three chambers 102, and the cooling water to all three chambers is derived from a single source 160, and is delivered at the same cooling water temperature. In alternate example apparatuses and methods, one source 160 supplies cooling water at cooling water temperature to one of the three chambers 102 at a first cooling water temperature, and a second source 160 supplies cooling water to one or two other chambers at a second cooling water temperature. In this way, one of the three chambers can process a chuck at the first cooling water temperature, and a second and optionally a third of the three chambers can process a chuck at a second cooling water temperature. Optionally, a third chamber may process a chuck at the first chuck temperature, at the second chuck temperature, or by using a third cooling water source 160 at a third cooling water temperature that is different from the first cooling water temperature and the second cooling water temperature.

Each of the three illustrated chambers 102 is connected to a source of chamber purge gas 162. The source 162 for each chamber may be the same source, or a different source.

Each of the three illustrated chambers 102 is also connected to a source of cooling channel purge gas 162. In example apparatuses and methods, for any single one of the chambers 102, source 162 that supplies purge gas to a cooling channel of chuck 110 may be the same or different from the source 162 that supplies chamber purge gas to space 104. For the three different chambers, some or all of the different chambers may receive chamber purge gas or cooling gas, or both, from a single source 162, or alternately from two or more different sources of purge gas; i.e., source 162, while shown as three separate units, may be a single unit that supplies the source gas to each of the three different chambers and to each chamber both as cooing purge gas and as chamber purge gas.

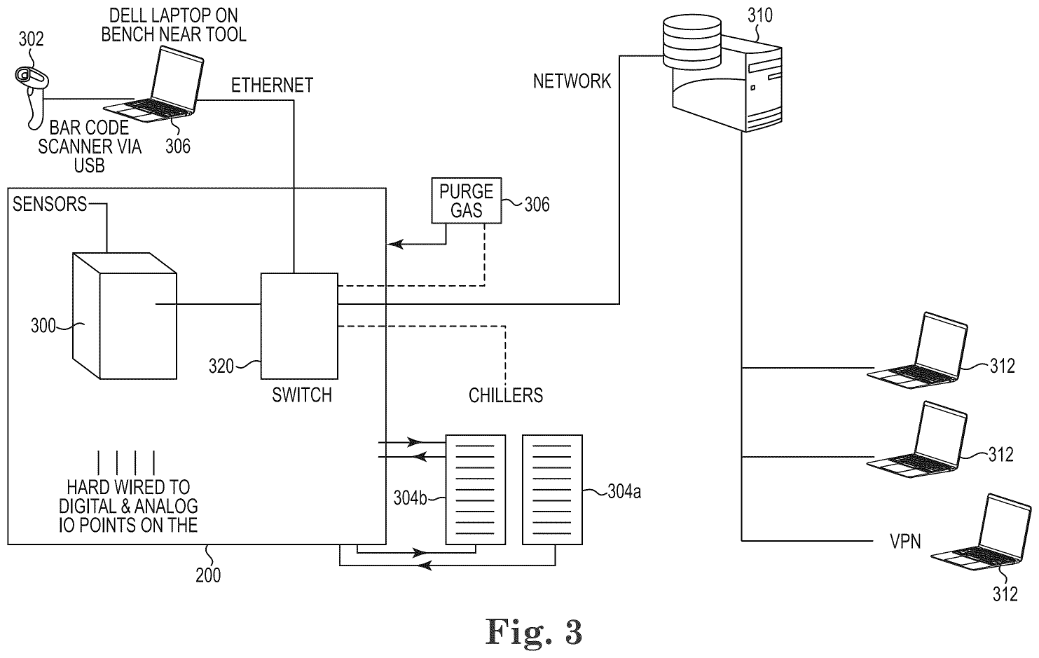

Referring to FIG. 3, illustrated is an example of an arrangement of electronic components that may be included as part of an apparatus (e.g., 200) of the present description or adapted to work with an apparatus. At FIG. 3, electronic controller 300 is a PLC in electronic communication with an apparatus 200 (represented by the box surrounding controller 300 and switch 320), such as an apparatus 200 (e.g., of FIG. 2). Apparatus 200 may include two or more individual chambers, sensors associated with each chamber, flow controls (e.g., flow meters), and fluid sources of apparatus 200, including one or two chillers 304a and 304b (temperature control fluid sources) and purge gas source 306. As illustrated, controller 300 is in electronic communication with electronic switch 320. Controller 300 is a PLC-type controller but other electronic control devices that include a central processing unit (CPU) and programmable control software may also be useful.

Laptop 300 and a connected bar code scanner 302 can be located near the apparatus, in electronic communication with the apparatus and with switch 320, which communications with controller 300. At a time of processing a chuck, scanner 302 can scan a barcode or other identifying feature of a chuck that will be processed and, using laptop 300, records the location, placement, and timing of the chuck being placed into a chamber of an apparatus for processing. Also shown at FIG. 3A is network hardware (server) 310 in communication with controller 300, and one or multiple remote computers 312, which can access network hardware 310 through a virtual private network (VPN).

In a first aspect, an apparatus for processing an electrostatic chuck, comprises: a chamber that contains a chamber atmosphere at a chamber interior, a source of chamber purge gas adapted to supply chamber purge gas to the chamber interior, a source of temperature control fluid adapted to supply temperature control fluid to the chamber interior, and a temperature sensor to measure a temperature at the chamber interior.

A second aspect according to the first aspect further comprises a humidity sensor to measure humidity of the chamber atmosphere.

A third aspect according to the first or second aspect further comprises: a first conduit to provide the temperature control fluid to the chamber, a second conduit to remove the temperature control fluid from the chamber, wherein the temperature sensor is adapted to measure a temperature of the temperature control fluid at the first conduit, and a second temperature sensor adapted to measure a temperature of the temperature control fluid at the second conduit.

A fourth aspect according to any of the preceding aspects further comprises a flow meter to control an amount of chamber purge gas supplied to the chamber from the source of chamber purge gas.

A fifth aspect according to any of the preceding aspects further comprises a pressure sensor at the chamber interior adapted to measure pressure of the temperature control fluid within the chamber.

A sixth aspect according to any of the preceding aspects further comprises an electronic controller in communication with: one or more sensors in the chamber, the source of chamber purge gas, and the source of temperature control fluid.

A seventh aspect according to the sixth aspect, wherein the electronic controller comprises a timer to control one or more of: a period of time during which the temperature control fluid is supplied to the chamber, a period of time during which the chamber purge gas is supplied to the chamber, or both.

An eighth aspect according to the sixth or seventh aspect wherein the electronic controller is adapted to record data during operation of the apparatus, the data comprising: temperature data from one or more temperature sensors within the chamber interior, humidity data from a humidity sensor within the chamber interior.

A ninth aspect according to any of the preceding aspects, further comprises an electrostatic chuck contained within the chamber interior, the electrostatic chuck comprising: a first layer, a second layer, a fluid flow channel passing through at least one of the two layers, and an adhesive between the first layer to the second layer, wherein the source of temperature control fluid is connected to the fluid flow channel.

A tenth aspect according to the ninth aspect further comprises a conduit that provides the temperature control fluid to an inlet of the fluid flow channel, and a conduit the receives the temperature control fluid from an outlet of the fluid flow channel.

An eleventh aspect according to the ninth or tenth aspect further comprises a pressure sensor to measure a pressure of the temperature control fluid.

A twelfth aspect according to one of the ninth through eleventh aspects, further comprises a source of purge gas adapted to supply channel purge gas to the fluid flow channel.

A thirteenth aspect according to any of the preceding aspects, further comprises: a second chamber that contains a second chamber atmosphere at a second chamber interior, a source of chamber purge gas adapted to supply chamber purge gas to the second chamber, a source of temperature control fluid adapted to supply temperature control fluid to the second chamber, and a temperature sensor to measure a temperature at the second chamber interior.

A fourteenth aspect according to the thirteenth aspect further comprises an electronic controller in communication with: one or more sensors of the chamber, one or more sensors of the second chamber, the source of chamber purge gas, and the source of temperature control fluid.

A fifteenth aspect according to the thirteenth or fourteenth aspect, further comprises a second source of temperature control fluid, wherein: the source of temperature control fluid is adapted to supply temperature control fluid to the chamber, and the second source of temperature control fluid is adapted to supply temperature control fluid to the second chamber.

A sixteenth aspect according to any of the thirteenth through fifteenth aspects, further comprises a chassis that supports: the chamber and the second chamber in a vertically-stacked orientation, and an electronic controller that communicates with: one or more sensors of the first chamber, one or more sensors of the second chamber, the source of chamber purge gas, and the source of temperature control fluid.

In a seventeenth aspect, a method of processing an electrostatic chuck is disclosed, the electrostatic chuck comprising: a first layer, a second layer, and an adhesive between the first layer and the second layer, the method comprising: with the chuck located within a chamber, the chamber comprising: a chamber atmosphere, and a temperature sensor, using an electronic controller to: control a temperature of the chuck, and control humidity in the chamber.

An eighteenth aspect according to the seventeenth aspect further comprises: controlling the temperature of the chuck maintain the temperature below 15 degrees Celsius, and controlling the humidity in the chamber by adding dry gas to the chamber in an amount that prevents condensation from forming at a surface of the chuck.

A nineteenth aspect according to the seventeenth or eighteenth aspect further comprises controlling the temperature of the chuck for a period of time sufficient to allow the adhesive to cure.

A twentieth aspect according to any of the seventeenth through nineteenth aspects, further comprises: placing the chuck in the chamber while the adhesive is un-cured, and with the chuck in the chamber, controlling the temperature of the chuck and allowing the adhesive to cure for a period of at least 40 minutes.

A twenty-first aspect according to any of the seventeenth through twentieth aspects, wherein: the chuck comprises a cooling channel passing through at least one of the two layers, the chamber comprises a source of temperature control fluid adapted to supply temperature control fluid to the cooling channel, and the temperature sensor measures a temperature of the temperature control fluid.

A twenty-second aspect according to the twenty-first aspect, further comprises passing channel purge gas through the cooling channel to remove liquid from the cooling channel.

A twenty-third aspect according to any of the seventeenth through twenty-second aspects, further comprises: recording the temperature of the chuck.

A twenty-fourth aspect according to any of the seventeenth through twenty-third aspects, further comprises delivering chamber purge gas to the chamber to reduce relative humidity of the chamber atmosphere.

A twenty-fifth aspect according to any of the seventeenth through twenty-fourth aspects, wherein the first layer is ceramic, the second layer is aluminum, and the adhesive is an epoxy adhesive.

A twenty-sixth aspect according any of the seventeenth through twenty-fifth aspects, further comprises processing the electrostatic chuck and a second electrostatic chuck located in a second chamber, the second electrostatic chuck comprising: a first layer, a second layer, a fluid flow channel passing through at least one of the two layers, and an adhesive between the first layer to the second layer, the second chamber comprising: a second chamber atmosphere, and a temperature sensor to measure a temperature of the second electrostatic chuck, the method comprising: with the second chuck located within the second chamber using an electronic controller to: control a temperature of the second chuck, and control humidity in the second chamber.

In a twenty-seventh aspect, an apparatus for processing an electrostatic chuck, comprises: a chamber that contains a chamber atmosphere at a chamber interior, and an electrostatic chuck, the electrostatic chuck comprising: a first layer, a second layer, a fluid flow channel passing through at least one of the two layers, and an adhesive between the first layer to the second layer, a source of temperature control fluid connected to the fluid flow channel, and a source of purge gas connected to the fluid flow channel.

A twenty-eighth aspect according to the twenty-seventh aspect, further comprises: a source of chamber purge gas adapted to supply chamber purge gas to the chamber, and a temperature sensor to measure a temperature of the electrostatic chuck.

A twenty-ninth aspect according to the twenty-seventh or twenty-eighth aspect, further comprises a humidity sensor to measure humidity of the chamber atmosphere.

A thirtieth aspect according to any one of the twenty-seventh through twenty-ninth aspects, further comprises an electronic controller in communication with: the source of temperature control fluid, and the source of chamber purge gas.

1. A method of processing an electrostatic chuck, the electrostatic chuck comprising a first layer, a second layer, and an adhesive between the first layer and the second layer, wherein the method comprises:
introducing a temperature control fluid at or below ambient temperature to control a temperature of the electrostatic chuck when the electrostatic chuck is located within a chamber, the chamber including a temperature sensor and defining a chamber interior having a chamber atmosphere;
introducing a chamber purge gas into the chamber to control humidity of the chamber atmosphere to prevent condensation on a surface of the electrostatic chuck; and
measuring a temperature at the chamber interior using the temperature sensor.

2. The method of claim 1, further comprising:
controlling the temperature of the chuck to maintain the temperature below 15 degrees Celsius.

3. The method of claim 1, further comprising controlling the temperature of the chuck for a period of time sufficient to allow the adhesive to cure.

4. The method of claim 1, further comprising:
placing the chuck in the chamber while the adhesive is un-cured, and
controlling the temperature of the chuck and allowing the adhesive to cure for a period of at least 40 minutes.

5. The method of claim 1, wherein:
the chuck comprises a cooling channel passing through at least one of the two layers, and the method further comprises flowing the temperature control fluid through the cooling channel to control the temperature of the electrostatic chuck.

6. The method of claim 5, further comprising passing channel purge gas through the cooling channel to remove liquid from the cooling channel.

7. The method of claim 1, further comprising: recording the temperature of the chuck.

8. The method of claim 1, further comprising delivering chamber purge gas to the chamber to reduce relative humidity of the chamber atmosphere.

9. The method of claim 1, wherein the first layer is ceramic, the second layer is aluminum, and the adhesive is an epoxy adhesive.

10. A method of processing an electrostatic chuck, the electrostatic chuck comprising a first layer, a second layer, an adhesive between the first layer and the second layer, and a cooling channel passing through at least one of the first or second layers, wherein the method comprises:
placing the electrostatic chuck in a chamber while the adhesive is in an uncured state, the chamber including at least one temperature sensor and defining a chamber interior having a chamber atmosphere;
flowing a temperature control fluid through the cooling channel at or below ambient temperature to maintain a temperature of the electrostatic chuck at or below 15 degrees Celsius and allowing the adhesive to cure for a period of at least 40 minutes; and
introducing a chamber purge gas into the chamber to control humidity of the chamber atmosphere to prevent condensation on a surface of the electrostatic chuck.
